(19) United States
(12) Patent Application Publication
(10) Pub. No.: US 2025/0324780 A1
(43) Pub. Date: Oct. 16, 2025

(54) COORDINATE CONVERSION METHOD OF MULTIPLE DIES ON A WAFER

(71) Applicant: Taiwan-Asia Semiconductor Corporation, Hsinchu City (TW)

(72) Inventors: Chih-Hsien LAIO, Hsinchu City (TW); Wei HSIEH, Hsinchu City (TW)

(21) Appl. No.: 18/908,048

(22) Filed: Oct. 7, 2024

(30) Foreign Application Priority Data
Apr. 12, 2024 (TW) 113113775

(51) Int. Cl. H01L 27/146; H01L 21/66

(52) U.S. Cl. CPC H10F 39/026; H01L 22/12

(57) ABSTRACT

A coordinate conversion method for multiple dies on a wafer is provided. The coordinate conversion method includes the following steps. First, provide a mechanical absolute coordinate of the dies on the wafer, where the mechanical absolute coordinate includes a horizontal coordinate and a vertical coordinate, and the horizontal coordinate and the vertical coordinate is not an integer. Secondly, a magnification factor is calculated, where the magnification factor is a ratio of a minimum horizontal spacing to a minimum vertical spacing between two adjacent dies, and the magnification factor is greater than 1. Finally, a relative coordinate is calculated, wherein the relative coordinate system is to replace one of the horizontal coordinate and the vertical coordinate in the mechanical absolute coordinate which is not an integer by multiply it with the magnification factor.

### CROSS-REFERENCES TO RELATED APPLICATIONS

This application claims the benefit of priority to Taiwanese Patent Application No. 113113775 filed on Apr. 12, 2024, which is hereby incorporated by reference in its entirety.

### BACKGROUND OF THE INVENTION

### Field of the Invention

The present invention relates to a coordinate generation method, and in particular to a coordinate conversion method between non-equally spaced dies on a wafer.

### Descriptions of the Related Art

A photosensitive die is a photoelectric conversion device. When light irradiates the photosensitive die, the photosensitive die can generate a corresponding change in current or voltage. Photosensitive dies are widely used in various optical instruments such as optical communications, photoelectric detectors, automatic brightness adjustment, spectral analysis, photosensitive circuits, photodetectors, cameras, etc. They are usually used to detect light intensity, measure spectrum or detect light signals.

The photosensitive die traditionally used in wearable devices is a square die with two sides equidistant. However, in order to maximize the area of the photosensitive die in the wearable device, the conventional photosensitive die has begun to change its shape. The original square die is converted into a regular hexagonal die. Please refer to FIG. 1A, which shows a schematic diagram of the arrangement of a plurality of hexagonal dies cut from a conventional wafer. Meanwhile, the arrangement of the hexagonal dies on the wafer is different from that of the die array with the traditional equidistant in the X/Y direction, and the lateral and longitudinal spacing between adjacent dies are unequal.

Generally speaking, after the die is cut on the wafer, the die needs to be sorted one by one from the wafer using die picking equipment. Electrical and other tests will be performed on the back-end process equipment. Before dies being pick up, an automatic optical inspection (AOI) machine usually needs to calibrate a mechanical absolute coordinate for each die on the wafer and then generate a relative coordinate to meet the coordinate reading requirements of different picking equipment. Specifically, an AOI machine is used to perform mechanical absolute coordinate calibration for each die on the wafer as shown in FIG. 1A to form a coordinate distribution result as shown in FIG. 1B.

Please refer to FIG. 1B, taking 16 dies (A1˜A4, B1˜B4, C1˜C4, D1˜D4) as an example. The coordinate distributions of these 16 dies are A1(0,0), B1(1,0), C1(2,0), D1(3,0), A2(0.5,1), B2(1.5,1), C2(2.5,1), D2(3.5,1), A3(0,2), B3(1,2), C3(2,2), D3(3,2), A4(0.5,3), B4(1.5,3), C4(2.5,3) and D4(3.5,3). Obviously, the lateral distance between adjacent dies, for example, between A1 and A2, is only 0.51 standard unit (1), while the longitudinal distance is one standard unit (1). However, the coordinate values that the current die picking equipment can read must be based on integers, and any non-integer coordinate values cannot be read. Therefore, the coordinates under the arrangement for hexagonal dies as shown in FIG. 1B with non-integer coordinate values do not comply with the coordinate output principle of die picking equipment. The arrangement for hexagonal dies will cause problems and difficulties on the equipment operation of the proceeding processes. Therefore, the conventional technology needs a new coordinate conversion method for the non-integer relative coordinate caused by the arrangement of different polygonal dies on the wafer so that the polygonal dies cut from the wafer can be smoothly transferred to the back-end processing equipment in the subsequent processes.

### SUMMARY OF THE INVENTION

The main objective of this invention is to provide an innovative method for coordinate conversion among a plurality of dies on a wafer, particularly focusing on the coordinate conversion method for the arrangement of polygonal dies on the wafer. This enables the smooth conversion of die coordinates with non-integer unit distances into relative coordinates with integer units, which can be used for subsequent processes such as electrical testing, dicing, AOI inspection, and other backend process equipment.

To achieve the above objective, the present invention discloses a coordinate conversion method for multiple dies on a wafer is provided. The coordinate conversion method includes the following steps. First, provide a mechanical absolute coordinate of the dies on the wafer, where the mechanical absolute coordinate includes a horizontal coordinate and a vertical coordinate, and the horizontal coordinate and the vertical coordinate is not an integer. Secondly, a magnification factor is calculated, where the magnification factor is a ratio of a minimum horizontal spacing to a minimum vertical spacing between two adjacent dies, and the magnification factor is greater than 1. Finally, a relative coordinate is calculated, wherein the relative coordinate system is to replace one of the horizontal coordinate and the vertical coordinate in the mechanical absolute coordinate which is not an integer by multiply it with the magnification factor.

In one embodiment of the coordinate conversion method of the present invention, wherein each of the dies is cut from the wafer and each of the dies is a polygon so that one of the horizontal coordinate and the vertical coordinate in the mechanical absolute coordinate is the non-integer.

In one embodiment of the coordinate conversion method of the present invention, wherein the magnification factor can be an integer or a decimal.

In one embodiment of the coordinate conversion method of the present invention, wherein each of the dies is a hexagonal die.

In one embodiment of the coordinate conversion method of the present invention, wherein the hexagonal die is a regular hexagonal die.

In one embodiment of the coordinate conversion method of the present invention, wherein each of the dies is a trapezoidal die.

In one embodiment of the coordinate conversion method of the present invention, wherein the trapezoidal die is an isosceles trapezoidal die.

To achieve the above objective, the present invention discloses a coordinate conversion method for multiple polygonal dies on a wafer is provided. The coordinate conversion method includes the following steps. First, provide a mechanical absolute coordinate of the polygonal dies on the wafer, wherein the mechanical absolute coordinate includes a horizontal coordinate and a vertical coordinate, and one of the horizontal coordinate and the vertical coordinate is a non-integer Secondly, a magnification factor is calculated, wherein the magnification factor is a ratio of a minimum horizontal spacing to a minimum vertical spacing between two of the adjacent polygonal dies, and the magnification factor is greater than 1. Finally, a relative coordinate is calculated, wherein the relative coordinate is to replace one of the horizontal coordinate and the vertical coordinate in the mechanical absolute coordinate which is the non-integer by multiplying it with the magnification factor.

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1A is a schematic diagram showing the layout of several hexagonal dies on a wafer;

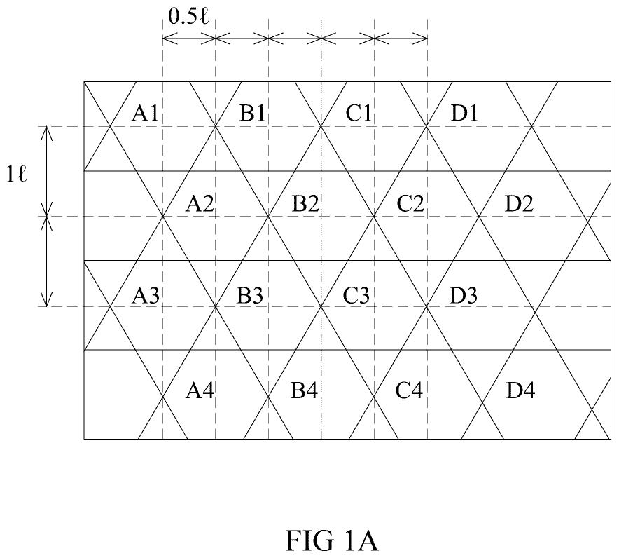

FIG. 1B is a schematic diagram showing the coordinate distribution of 16 dies of FIG. 1A;

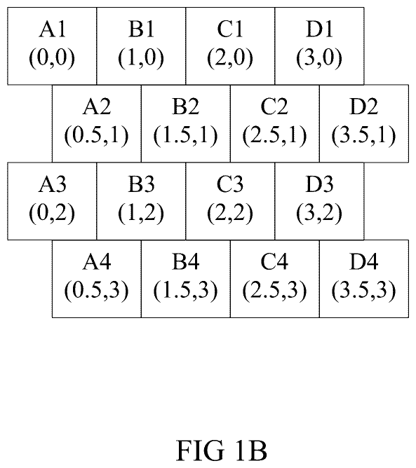

FIG. 2A is a schematic diagram showing the layout of several regular hexagonal dies on a wafer;

FIG. 2B is a schematic diagram showing the distribution of mechanical absolute coordinates of 16 dies of FIG. 2A;

FIG. 2C is a schematic diagram showing the distribution of relative coordinates after coordinate conversion of 16 dies of FIG. 2A;

FIG. 2D is a schematic diagram showing the distribution of dies on a wafer after coordinate conversion into a relative coordinate; and

FIG. 3 is a schematic diagram showing the layout of isosceles trapezoidal dies on a wafer.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

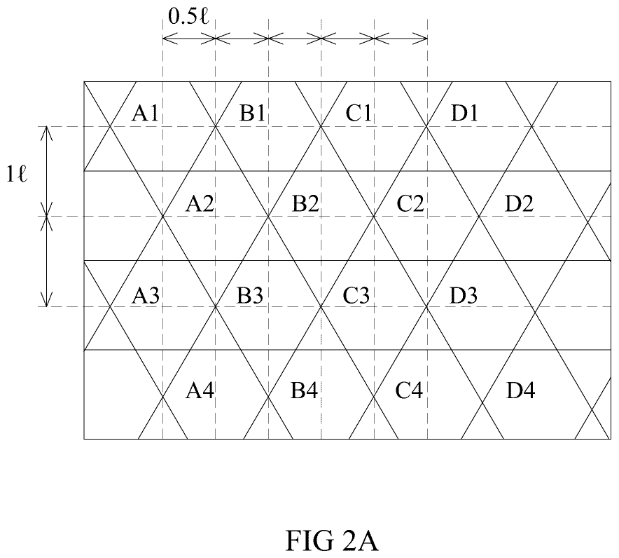

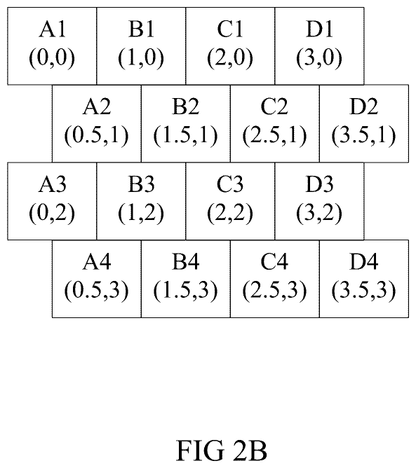

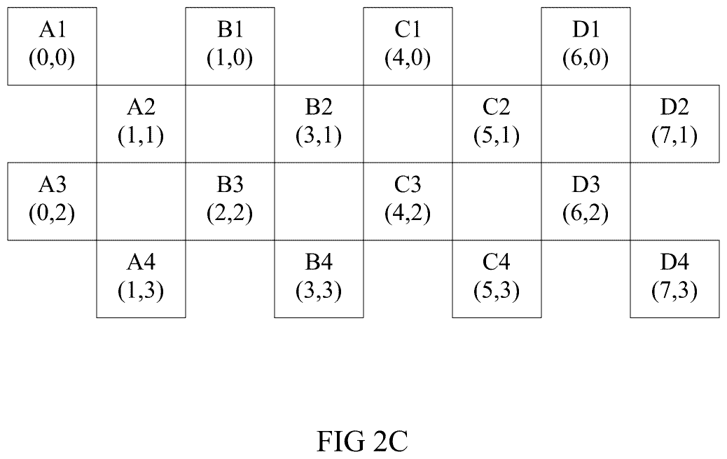

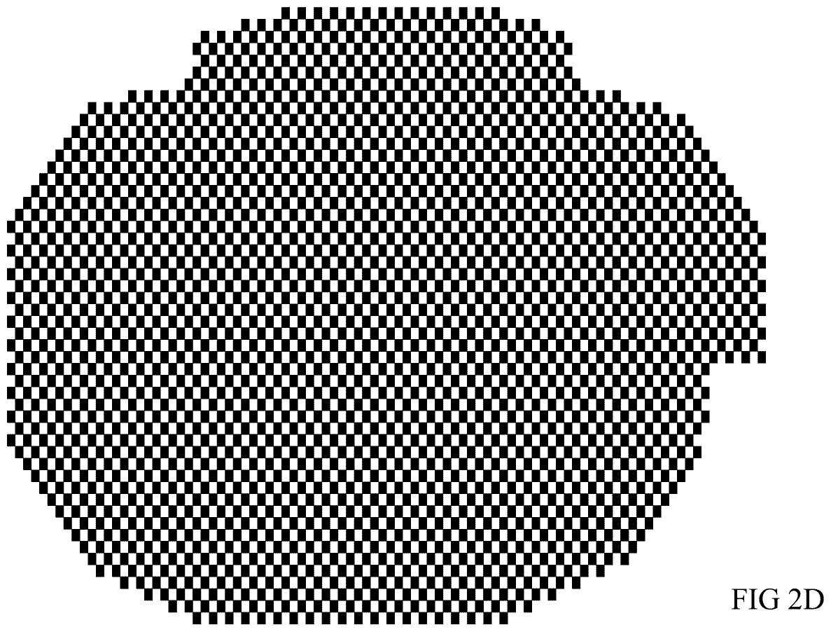

Please refer to FIG. 2A, which shows the wafer after the front-end epitaxial process being processed and polygonal dies, such as hexagonal dies, being cut. After the hexagonal dies being cut, a layout of a plurality of hexagonal dies will be formed on the wafer, specifically a layout of regular hexagonal dies formed thereon. Each regular hexagonal die has a mechanical absolute coordinate at its center, and the mechanical absolute coordinate of each die includes a horizontal coordinate and a vertical coordinate. In the embodiment shown in FIG. 2A, this arrangement of regular hexagonal dies differs from the matrix arrangement of traditional square dies. The lateral and longitudinal spacing between adjacent dies are unequal so that one of the horizontal or vertical coordinates in the mechanical absolute coordinate is a non-integer. Specifically, the minimum longitudinal spacing between two adjacent dies is 11 standard unit (1) which is a feature size of a die, while the minimum lateral spacing between two adjacent dies is 0.51.

As described in the descriptions of the related art, the mechanical absolute coordinates of some regular hexagonal dies on the wafer interpreted by an automatic optical inspection (AOI) machine will obtain non-integer coordinate values. If these non-integer coordinate values are not properly converted, the back-end process equipment will be unable to obtain the coordinates of each die, resulting in unsuccessful subsequent operations. In view of this, the present invention proposes an innovative coordinate conversion method that can effectively convert all mechanical absolute coordinates with non-integer values into relative coordinates with integer units to facilitate the back-end process operations.

The coordinate conversion method of the present invention comprises the following steps. First, in step S01, a mechanical absolute coordinate for each die on a wafer is provided, wherein the mechanical absolute coordinate includes a horizontal coordinate and a vertical coordinate, and one of the horizontal coordinate and the vertical coordinate is a non-integer. Next, in step S02, a magnification factor is calculated, where the magnification factor is the ratio of the minimum horizontal spacing to the minimum vertical spacing between any two adjacent dies on the wafer, and the magnification factor is greater than 1. In other words, the magnification factor is the ratio of the smaller value to the larger value between the minimum horizontal spacing and the minimum vertical spacing. This magnification factor can be an integer or a decimal but cannot have a remainder. Finally, in step S03, a relative coordinate is calculated, wherein the relative coordinate replaces the non-integer horizontal or vertical coordinate in the original mechanical absolute coordinate by multiplying it by the magnification factor calculated in step S02, while retaining the other integer coordinate. Specifically, multiplying the non-integer horizontal or vertical coordinate by the magnification factor converts it into an integer horizontal or vertical coordinate. For example, if the original mechanical absolute coordinate (x, y) has a non-integer horizontal coordinate x, then this coordinate needs to be converted into a relative coordinate (x′, y′). During the coordinate conversion, the non-integer horizontal coordinate x is multiplied by the magnification factor calculated in step S02 to obtain the converted integer relative horizontal coordinate x′. On the other hand, since the original vertical coordinate y is already an integer, it remains unchanged during the coordinate conversion. Therefore, the relative vertical coordinate y′ is the same as the original mechanical absolute coordinate vertical coordinate y.

The method with an example based on the implementation is shown in FIG. 2B. FIG. 2B displays the mechanical absolute coordinates of 16 dies including A1˜A4, B1˜B4, C1˜C4, D1˜D4: A1(0,0), B1(1,0), C1(2,0), D1(3,0), A2(0.5,1), B2(1.5,1), C2(2.5,1), D2(3.5,1), A3(0,2), B3(1,2), C3(2,2), D3(3,2), A4(0.5,3), B4(1.5,3), C4(2.5,3), D4(3.5,3).

Observing these mechanical absolute coordinates reveals that some dies have non-integer horizontal coordinates so it is necessary to perform the coordinate conversion. Before performing the coordinate conversion, it's essential to calculate the magnification factor. Taking adjacent dies A1 and A2 as an example, the horizontal spacing between them is 0.51, and the vertical spacing is 11. Therefore, the horizontal axis needs to be magnified. In this embodiment, the magnification factor for the horizontal axis is the ratio of the horizontal spacing to the vertical spacing, i.e., magnification factor=11/0.5l=2. After calculating the magnification factor, the coordinate conversion proceeds. For die A2, for instance, the original mechanical absolute coordinate A2(0.5,1) has a horizontal coordinate of 0.5, which needs to be multiplied by the magnification factor 2 to convert it to 1. On the other hand, the vertical coordinate value 1 remains unchanged. Thus, after coordinate conversion, the relative coordinate of die A2 becomes (1,1). Refer to FIG. 2C, which illustrates the relative coordinates after the coordinate conversion for these 16 dies. It is evident that after coordinate conversion, the relative coordinates of all dies are integer values which conform to the principle of integer relative coordinates. This format is compatible with coordinate requirements for reading coordinates in subsequent processes across various devices, including electrical testing, AOI inspection, and others. Please refer to FIG. 2D, which shows a schematic diagram of the distribution of all dies on the entire wafer after the aforementioned coordinate conversion in relative coordinates.

The above example is just one embodiment. The coordinate conversion method disclosed in this invention can be applied to other patterns with non-integer unit distances between dies. Below is an example listing the magnification factors and corresponding relative coordinate values after magnified for various different unit spacing conditions:

TABLE 1

| spacing | 0.11 | 0.21 | 0.251 | 0.41 | 0.51 | 0.81 |
|---|---|---|---|---|---|---|
| magnification factor | 10 | 5 | 4 | 2.5 | 2 | 1.25 |
| coordinate values after | 1 | 1 | 1 | 1 | 1 | 1 |
| magnified | | | | | | |

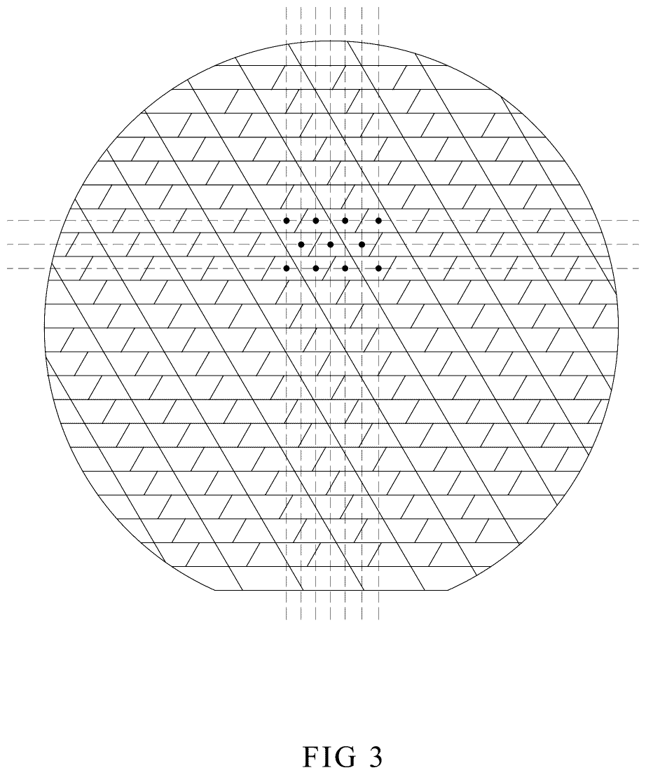

Additionally, it should be noted that the above explanation has only used hexagonal dies as an example. In other embodiments, the present invention can be applied to patterns of dies cut into various polygonal shapes on a wafer. For example, refer to FIG. 3, which illustrates multiple trapezoid-shaped dies cut on a wafer, including but not limited to isosceles trapezoid-shaped dies, with adjacent dies arranged in an inverted top-bottom pattern. The arrangement of isosceles trapezoid-shaped dies shown in FIG. 3 also exhibits a spatial relationship similar to the staggered arrangement of adjacent dies described above. The spatial relationship results in some dies having a minimum horizontal spacing between them of only half the die feature unit size (1) (i.e., the minimum vertical spacing) and causes the mechanical absolute coordinate values of some dies in the die layout to be non-integer. Therefore, it is necessary to use the coordinate conversion method disclosed above in this invention to perform coordinate conversion for subsequent processing stages.

The above embodiments are used only to illustrate the implementations of the present invention and to explain the technical features of the present invention, and are not used to limit the scope of the present invention. Any modifications or equivalent arrangements that can be easily accomplished by people skilled in the art are considered to fall within the scope of the present invention, and the scope of the present invention should be limited by the claims of the patent application.

What is claimed is:

1. A coordinate conversion method for a plurality of dies on a wafer, the coordinate conversion method includes the following steps:
providing a mechanical absolute coordinate of the dies on the wafer, wherein the mechanical absolute coordinate includes a horizontal coordinate and a vertical coordinate, and one of the horizontal coordinate and the vertical coordinate is a non-integer;
calculating a magnification factor, wherein the magnification factor is a ratio of a minimum horizontal spacing to a minimum vertical spacing between two of the adjacent dies, and the magnification factor is greater than 1; and
calculating a relative coordinate, wherein the relative coordinate is to replace one of the horizontal coordinate and the vertical coordinate in the mechanical absolute coordinate which is the non-integer by multiplying it with the magnification factor.

2. The coordinate conversion method of claim 1, wherein each of the dies is cut from the wafer and each of the dies is a polygon so that one of the horizontal coordinate and the vertical coordinate in the mechanical absolute coordinate is the non-integer.

3. The coordinate conversion method of claim 1, wherein the magnification factor can be an integer or a decimal.

4. The coordinate conversion method of claim 2, wherein each of the dies is a hexagonal die.

5. The coordinate conversion method of claim 4, wherein the hexagonal die is a regular hexagonal die.

6. The coordinate conversion method of claim 2, wherein each of the dies is a trapezoidal die.

7. The coordinate conversion method of claim 6, wherein the trapezoidal die is an isosceles trapezoidal die.

8. A coordinate conversion method for a plurality of polygonal dies on a wafer, the coordinate conversion method includes the following steps:
providing a mechanical absolute coordinate of the polygonal dies on the wafer, wherein the mechanical absolute coordinate includes a horizontal coordinate and a vertical coordinate, and one of the horizontal coordinate and the vertical coordinate is a non-integer;
calculating a magnification factor, wherein the magnification factor is a ratio of a minimum horizontal spacing to a minimum vertical spacing between two of the adjacent polygonal dies, and the magnification factor is greater than 1; and
calculating a relative coordinate, wherein the relative coordinate is to replace one of the horizontal coordinate and the vertical coordinate in the mechanical absolute coordinate which is the non-integer by multiplying it with the magnification factor.

9. The coordinate conversion method of claim 8, wherein the magnification factor can be an integer or a decimal.

10. The coordinate conversion method of claim 8, wherein each of the polygonal dies is a hexagonal die.

11. The coordinate conversion method of claim 10, wherein the hexagonal die is a regular hexagonal die.

12. The coordinate conversion method of claim 8, wherein each of the polygonal dies is a trapezoidal die.

13. The coordinate conversion method of claim 12, wherein the trapezoidal die is an isosceles trapezoidal die.
